(19) United States
(12) Patent Application Publication
(10) Pub. No.: US 2012/0257336 A1
(43) Pub. Date: Oct. 11, 2012

(54) ANTI-THEFT DETERRENT PROTECTION KIT AND A METHOD OF ASSEMBLING AND USING SAID KIT

(75) Inventor: Ronald G. Wolff, JR., Appleton, WI (US)

(73) Assignee: Snagg, LLC, Appleton, WI (US)

(21) Appl. No.: 13/435,787

(22) Filed: Mar. 30, 2012

Related U.S. Application Data
(60) Provisional application No. 61/516,791, filed on Apr. 7, 2011.

(51) Int. Cl. H05K 5/00; B23P 17/04

(52) U.S. Cl. 361/679.01; 29/428

(57) ABSTRACT

An anti-theft deterrent protection kit comprising a case, a tracking device coupled with the case, and a securing means for securing the tracking device to an object.

### RELATED APPLICATION

The present patent document claims the benefit of the filing date under 35 U.S.C. §119(e) of Provisional U.S. patent application Ser. No. 61/516,791, filed Apr. 7, 2011, which is hereby incorporated by reference.

### FIELD OF THE INVENTION

This invention relates to a package for an anti-theft deterrent protection kit and a method of assembling and using the kit.

### BACKGROUND OF THE INVENTION

Today, people buy, sell, trade, barter, donate, give away or steal various articles, items and products that are relatively small enough in size that they can be easily carried by one person. Some such articles, items and products can be costly and expensive to acquire. People desire to acquire or own certain articles, items and products for various reasons. Some of such articles, items and products are acquired to be consumed, such as food, non-alcoholic beverages, and alcoholic beverages such as beer, wine and whiskey. Others articles, items and products are acquired to be used at home or at work, such as computers, TV's, DVD's, kitchen utensils or handheld tools needed to performs one's work. Still other articles, items and products are needed to perform certain jobs, like construction equipment, generators, compressors, skill saws, power drills, etc. Still other articles, items and products are acquired to be played with, such as musical instruments, hunting and fishing equipment, and sporting goods. Still other articles, items and products are acquired as part of a collection, such as ceramic figurines, glassware, paperweights, etc. Still further, other articles, items and products are acquired simply to convey a certain status symbol. A status symbol is something, such as a possession or an activity, by which one's social or economic prestige is measured. For example, one who owns a Stradivarius violin is a very wealthy person and one who plays a Stradivarius violin, such as Issac Stern, is a great virtuosos.

Certain articles, items and products are owned by a large percentage of the population simply because a large number of people ride a bicycle, play some kind of a musical instrument, listen to music, watch TV, use a computer, own an I-pad, engage in some type of sport, participate in a hobby, or hunt and fish. Because of this, very large numbers of bicycles, musical instruments, computers, TV's, DVD's, guns, handheld tools, etc. have been manufactured and sold, and many new articles, items and products are being manufactured every day. Some of such articles, items and products can become very costly because they were the first ones produced, are considered to be of the finest quality, were manufactured by a certain company that is no longer in business, were constructed of the finest materials, were autographed by a famous person, etc. Still other articles, items and products are manufactured in limited quantities, may be handmade, or are made by a famous craftsman, and therefore are considered valuable and rare. Hence, they are expensive to own or acquire.

Today, there are roughly five million guns in the United States. It has been estimated that about 500,000 guns are stolen each year. Such guns often reappear in pawn shops, gun shops or are marketed to various people who are unaware that the gun has been stolen. Many times, the serial number stamped into the barrel of the gun has been ground off. Very often, guns are resold to people who become involved in new criminal activities. Such guns include: rifles, shotguns, pistols, revolvers, derringers, etc. Many such guns include a wood or synthetic stock or pistol grip.

Likewise, it has been estimated that there are over a billion bicycles in the world today and millions are stolen each year. Many other expensive articles such as musical instruments, computers, TV's and various electronic gadgets are produced in very large quantities and every day a number are stolen because they can be easily fenced and resold.

Currently, there is a pressing need for a simple and inexpensive anti-theft deterrent protection kit which includes a tracking device, such as a radio frequency identification device, which can be secured to an article to deter one from stealing and reselling the article. There is also a need for a method of assembling and using the anti-theft deterrent protection kit to mark and identify articles, to have law enforcement personnel scan such articles before they are offered for resale, and to track ownership of the articles when they are being legitimately resold. Individuals are also demanding that such anti-theft deterrent protection kits be made available as Do-It-Yourself kits which can be sold at a variety of retailers, such as at: WalMart, Target, Home Depot, Lowes, etc. This would allow individuals to secure an anti-theft deterrent device to any article which they would like to protect.

Now a package for an anti-theft deterrent protection kit has been invented which includes a tracking device, namely a radio frequency identification device (RFID), that can be secured to an article so as to track the ownership of the article. A method of assembling and using the anti-theft deterrent protection kit has also been invented which allows law enforcement personnel to scan articles to determine the rightful owner and this hopefully will deter one from stealing and trying to sell the article to others through pawn shops.

### SUMMARY OF THE INVENTION

Briefly, this invention relates to a package for anti-theft deterrent protection kit, and a method of assembling and using the kit. The package includes a case having a front panel hinged to a back panel. The back panel has a first major surface with a circular indentation formed therein. The circular indentation has a center point and a raised protrusion extending upward from the center point. The package also includes a disk sized to fit within the circular indentation. The disk has a central aperture formed therethrough which is sized to fit over the raised protrusion and be retained thereon. The disk has a first aperture, a second aperture and a third aperture formed therethrough. The first, second and third apertures are spaced apart from the central aperture. The first aperture is sized and configured to receive a drill bit therein, the second aperture is sized and configured to receive a tracking device therein, and the third aperture is sized and configured to receive a first pre-assembled unit of adhesive and/or putty therein. The package further includes a fastener for temporarily retaining the drill bit in the first aperture and a fastener for temporarily retaining the tracking device in the second aperture.

The method of assembling and using the anti-theft deterrent protection kit includes assembling a kit which includes a drill bit, a tracking device in the form of a radio frequency identification device (RFID) having a retrievable serial number, an adhesive, and/or putty, and an instruction manual on how a consumer should secure the tracking device to an article. The kit is then marketed to a consumer. The consumer is instructed to use the drill bit to drill an aperture in the article, in an inconspicuous location, and use the adhesive to secure the tracking device in the aperture. If it is impractical to drill a hole, the tracking device can be glued or secured to the article in some other fashion. The consumer is then asked to supply pertinent personal data and information on the article, to which the radio frequency identification device has been secured, to a computer data base. Law enforcement personnel are educated on how to scan various articles to see if they contain a radio frequency identification device. Law enforcement personnel are also taught how to access the computer data base and input any retrieved serial numbers to obtain information on particular articles and to identify the legitimate owner. Law enforcement personnel will be notified when an article, which has been entered into the computer data base, has been reported as having been stolen and will be supplied with the personal data on the legitimate owner and the information on the article. The legitimate owner will be notified when the stolen article has been found and recovered.

The method of assembling and using the anti-theft deterrent protection kit also includes assembling a kit which includes a drill bit, a tracking device in the form of a radio frequency identification device (RFID) having a retrievable serial number, an adhesive, and/or putty, and an instruction manual on how a consumer should secure the tracking device to an article. The kit is then marketed to a consumer. The consumer is instructed to drill an aperture in the article, in an inconspicuous location, and use the adhesive to secure the tracking device in the aperture. The consumer is then asked to supply pertinent personal data and information on the article, to which the tracking device has been secured, to a computer data base. Law enforcement personnel are educated on how to scan articles that may contain one of the radio frequency identification devices to obtain the retrievable serial number. Law enforcement personnel are also educated on how to access the computer data base and input the retrieved serial number. The law enforcement personnel are encouraged to scan various articles taken in by pawn shops before such articles are made available for sale to the general public. The law enforcement personnel are also encouraged to access the computer data base and input a retrieved serial number to find out if an article has been stolen. If the article appears to be stolen, the law enforcement personnel are encouraged to confiscate the article and notify the legitimate owner that the stolen article has been found and recovered.

The general object of this invention is to provide a package for an antitheft deterrent protection kit which includes a tracking device, such as a radio frequency identification device (RFID). A more specific object of this invention is to provide a method of assembling and using an anti-theft deterrent protection kit to monitor legitimate ownership of the article and to allow for a legitimate transfer of the article by the rightful owner.

Another object of this invention is to provide an anti-theft deterrent protection kit, which includes a radio frequency identification device, wherein the device can be secured to an article to deter one from stealing and trying to pawn or fence the article.

A further object of this invention is to provide a package, about the size of a DVD case, which includes all the components of an anti-theft deterrent protection kit along with instructions on how to use the kit.

Still further, an object of this invention is to provide a method of monitoring potentially stolen articles which are being readied for resale at pawn shops, second hand stores, discount stores, etc., by using a radio frequency identification device which has been secured to an article in an inconspicuous location.

Still another object of this invention is to provide a method of monitoring potentially stolen articles which are being readied for resale at specialty stores such as: gun shops, music stores, and retailers who sell second hand sporting equipment.

Still further, an object of this invention is to provide a method whereby law enforcement personnel can search, find and monitor the movement of stolen property.

Other objects and advantages of the present invention will become more apparent to those skilled in the art in view of the following description and the accompanying drawings.

### BRIEF DESCRIPTION OF THE DRAWINGS

FIG. 1 is a front view of a package containing an anti-theft deterrent protection kit with the instruction manual removed to show the disk.

FIG. 2 is a rear view of the package shown in FIG. 1.

FIG. 3 is a front view of the anti-theft deterrent protection kit shown in FIG. 1 after the front panel has been rotated to an open position relative to the back panel.

FIG. 4 is an end view of the anti-theft deterrent protection kit shown in the open position and taken along line 4-4 of FIG. 3.

FIG. 5 is a front view of the disk retained on the back panel of the package shown in FIG. 1.

FIG. 6 is a side view of the disk shown in FIG. 5.

FIG. 7 is a side view of a drill bit.

FIG. 8 is a side view of a radio frequency identification device.

FIG. 9 is a cross-sectional view of the radio frequency identification device taken along line 9-9 of FIG. 8.

FIG. 10 is a front view of a packet containing two separate, pre-assembled units of resin which can be combined to form a quick drying adhesive.

FIG. 11 is a side view of the packet shown in FIG. 10.

FIG. 12 is a front view of a sticker.

FIG. 13 is a side view of the sticker shown in FIG. 12.

FIG. 14 is a flow diagram of a method for assembling and using the anti-theft deterrent protection kit.

FIG. 15 is a flow diagram of an alternative method for assembling and using the anti-theft deterrent protection kit.

### DETAILED DESCRIPTION OF THE INVENTION

Referring to FIGS. 1-3, a package 10 is shown for an anti-theft deterrent protection kit 12. The package 10 includes a case 14 having a front panel 16 attached to a back panel 18 by a pair of hinges 20. The case 14 can be formed from a variety of materials. Desirably, the case 14 is formed from plastic, paper or some other kind of material. By “plastic” it is meant any of various organic compounds produced by polymerization and capable of being molded, extruded, cast into shapes and film. The plastic can be clear or transparent such that one can easily see through it. The plastic could also be opaque or colored. By transparent it is meant capable of transmitting light so that objects or images can be seen as if there were no intervening material. By “opaque” it is meant impenetrable by light; neither transparent nor translucent. By “color” it is meant that aspect of things that is caused by differing qualities of the light reflected or emitted by them, definable in terms of the observer or of the light. Desirably, the plastic is clear or transparent.

Referring to FIGS. 1 and 3, each of the pair of hinges 20, 20 consist of a pin 22 which engages with an aperture 24. The pins 22, 22 are secured to the front panel 16 and the apertures 24, 24 are formed in the back panel 18. The structure of the front and back panels, 16 and 18 respectively, can be altered such that the pins 22, 22 are secured to the back panel 18 and the apertures 24, 24 are formed in the front panel 16, if desired. The pair of hinges 20, 20 allows the front panel 16 to rotate relative to the back panel 18 between a closed position, depicted in FIG. 1 and an open position, depicted in FIG. 3. Desirably, the front panel 16 can rotate 180 degrees relative to the back panel 18 from a closed position to an open position. The pins 22, 22 of the pair of hinges 20, 20 can also be formed from any material but desirably are formed from plastic. The pins 22, 22 can be formed when the front panel 16 is molded or formed. Likewise, the apertures 24, 24 can be formed when the back panel 18 is being molded or formed.

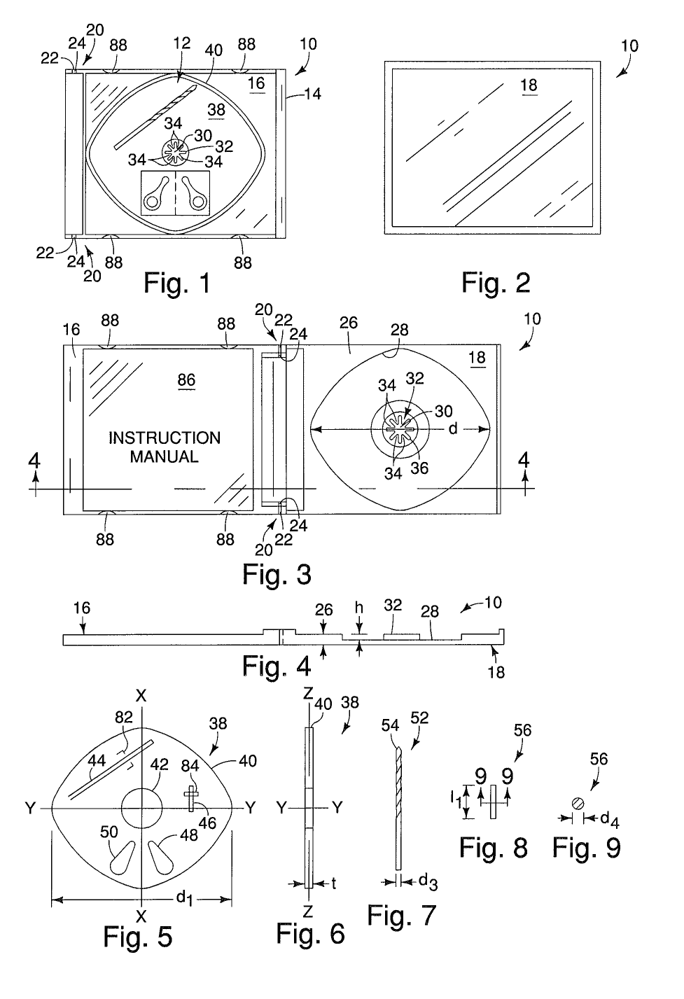

Referring now to FIGS. 2, 3 and 4, the back panel 18 has a first major surface 26 with a circular indentation 28 formed therein. The circular indentation 28 has a diameter d which can vary in dimension. Desirably, the diameter d of the circular indentation 28 is at least about 3 inches. More desirably, the diameter d of the circular indentation 28 is at least about 4 inches. Even more desirably, the diameter d of the circular indentation 28 is at least about 4.75 inches. The circular indentation 28 also has a height h which can also vary, see FIG. 4. The height h of the circular indentation 28 can range from between about 0.01 inches to about 0.3 inches. Desirably, the height h of the circular indentation 28 ranges from between about 0.05 inches to about 0.2 inches. More desirably, the height h of the circular indentation 28 ranges from between about 0.1 inches to about 0.15 inches. Even more desirably, the height h of the circular indentation 28 is at least about 0.12 inches.

Referring to FIGS. 3-5, the circular indentation 28 has a center point 30 and a raised protrusion 32 extending upward approximate the center point 30. Desirably, the raised protrusion 32 is coaxially aligned with the center point 30. The raised protrusion 32 can vary in configuration. As depicted, the raised protrusion 32 consists of a plurality of inwardly extending L-shaped, radial fingers 34. The height and length of each L-shaped finger can vary to suit one's particular needs. Each L-shaped, radial finger 34 is spaced apart from an adjacent finger 34 by a slot 36. The width of the fingers 34 and width of the slots 36 can vary. Desirably, each of the fingers 34 will be wider than each of the slots 36. The width of each of the fingers 34 can be the same or be different. Likewise, the width of each of the slots 36 can be the same or be different.

It should be noted that each of the fingers 34 is shown being spaced apart from the center point 30 by 0.1 inches or more. However, one or more of the fingers 34 can be constructed such that they extend completely across the center point 30, if desired. In fact, one finger 34 could extend to and be made a part of an oppositely aligned finger 34, if desired. One skilled in the art will be able to envision multiple configurations for the plurality of fingers 34.

Still referring to FIGS. 3-5, the plurality of fingers 34 cooperate with one another to form the raised protrusion 32 which is an attachment or holding mechanism for retaining a disk 38. By “disk” it is meant a thin, flat, circular object or plate. The disk 38 can be constructed from various materials. The disk 38 can be constructed from a single material, be constructed from two or more materials, be a composite material, or be a laminate that is formed from two or more layers of different or similar materials. Desirably, the disk 38 is made from plastic. Plastic is a relatively inexpensive material from which the disk 38 can be formed. The same plastic used to form the case 14 can be used to form the disk 38. More desirably, the disk 38 is made from cardboard. Cardboard is a relatively inexpensive material from which the disk 38 can be constructed. When the disk 38 is formed from cardboard, it may be thicker than a disk 38 formed from plastic since plastic tends to be a more rigid material.

Referring now to FIGS. 5 and 6, the disk 38 has a longitudinal central axis X-X, a transverse central axis Y-Y, and a vertical central axis Z-Z. The disk 38 has a diameter which can vary in dimension. Desirably, the diameter d₁ of the disk 38 is slightly less than the diameter d of the circular indentation 28. By “slightly less” it is meant a dimension of less than about 0.2 inches. Desirably, a dimension of less than about 0.15 inches. More desirably, a dimension of less than about 0.1 inches.

The diameter d₁ of the disk 38 should be at least about 3 inches. More desirably, the diameter d₁ of the disk 38 should be at least about 4 inches. Even more desirably, the diameter d₁ of the disk 38 should be at least about 4.5 inches.

The disk 38 also has a thickness t, see FIG. 6, which can vary in dimension. The thickness t of the disk 38 should be less than about 0.2 inches. Desirably, the thickness t of the disk 38 should be less than about 0.1 inches. More desirably, the thickness t of the disk 38 should be less than about 0.08 inches. When the disc 38 is formed from plastic, the thickness t can be relatively thin. The disk 38 is sized to fit within the circular indentation 28. The disk 38 has an outer periphery 40 and the disk 38 is sized to such that its diameter d₁ is slightly smaller than the diameter d of the circular indentation 28. Desirably, the diameter d₁ of the disk 38 is at least about 0.05 inches smaller than the diameter d of the circular indentation 28. More desirably, the diameter d₁ of the disk 38 is at least about 0.1 inches smaller than the diameter d of the circular indentation 28. Even more desirably, the diameter d₁ of the disk 38 is at least about 0.2 inches smaller than the diameter d of the circular indentation 28.

The disk 38 also has a central aperture 42 formed therethrough. The central aperture 42 is sized to fit over and snugly engage with the raised protrusion 32 formed on the back panel 18. The central aperture 42 has a diameter d₂ which can vary in dimension. The diameter d₂ of the central aperture 42 can range from between about 0.2 inches to about 1.0 inches. Desirably, the diameter d₂ of the central aperture 42 will range from between about 0.25 inches to about 0.75 inches. Even more desirably, the diameter d₂ of the central aperture 42 will range from between about 0.3 inches to about 0.6 inches. Most desirably, the diameter d₂ of the central aperture 42 will be about 0.5 inches. The disk 38 can easily rotate on the raised protrusion 32. However, the raised protrusion 32 will retain or frictionally hold the disk 38 such that a minimum amount of force is needed to remove the disk 38 from the raised protrusion 32. In other words, the raised protrusion 32 acts as a retainer for the disk 38 and will prevent the disk 38 from sliding around or falling out of the case 14 when the package 10 is opened. In short, the raised protrusion 32 frictionally retains the disk 38 thereon.

Still referring to FIG. 5, the disk 38 also includes a first aperture 44, a second aperture 46, and a third aperture 48 formed therethrough. Optionally, the disk 38 can also include a fourth aperture 50 which is aligned adjacent to the third aperture 48. Additional apertures can also be formed through the disk 38, if required. The first, second, third apertures, 44, 46 and 48 respectively, and the fourth aperture 50 when it is present, are all spaced apart or away from the central aperture 42. The first, second, third apertures, 44, 46 and 48 respectively, and the fourth aperture 50 when it is present, should be spaced at least about 0.5 inches away from the central aperture 42. The first, second, and third apertures, 44, 46 and 48 respectively, and the fourth aperture 50 when it is present, can be located radially about the disk 38. For example, the first aperture 44 can be located at an eleven o'clock position, the second aperture 46 can be located at a two o′clock position, the third aperture 48 can be located at a five thirty o'clock position, and the fourth aperture 50, when present, can be located at a six thirty position.

Referring to FIGS. 5 and 7, the first aperture 44 is sized and configured to receive a drill bit 52 therein. By “drill bit” it is meant a sharp pointed tool with a twist extending rearward from the point which is used to drill and/or bore an aperture in a solid or semi-solid material, such as wood, metal, steel, plastic, a composite material, etc. The drill bit 52 is designed to be inserted into the chuck end of a manual drill, a power drill, a drill press, etc. The drill bit 52 has a diameter d₃ and a length I. The diameter d₃ and length I of the drill bit 52 can vary. The diameter d₃ of the drill bit 52 is relatively small, such as ⅛ of an inch, 3/32 of an inch, 1/16 of an inch, etc. The drill bit 52 is used to form a hole or aperture in an article such that a tracking device can be inserted therein. Since the tracking device is relatively small in diameter and length, the size of the hole or aperture formed by the drill bit 52 can be relatively small. For most applications, the diameter d₃ of the drill bit 52 is 3/32 of an inch. As stated above, the length I of the drill bit 52 can also vary. Typically, the drill bit 52 can have a length ranging from between about 2 inches to about 3 inches. Desirably, the length I of the drill bit is about 2.5 inches or less. More desirably, the length I of the drill bit 52 is about 2.25 inches or less.

The drill bit 52 has a sharp tip or point 54. The tip or point 54 can be hardened or be constructed from a material that is very hard so that it can form a hole or aperture in a solid or semi-solid material. The tip or point 54 can be formed from carbide, diamond or some other hard material known to those skilled in the tool making art. Carbide is a hard material made of compacted binary compounds of carbon and heavy metals and is used to make tools that cut metal. Diamonds are an extremely hard crystalline form of carbon that are used to make cutting tools. Alternatively, the entire drill bit 52 can be formed from a single material, such as from a hardened steel.

Referring to FIGS. 5, 8 and 9, the second aperture 46 is sized and configured to receive a tracking device 56. The tracking device 56 can be almost any kind of tracking device known to those skilled in the art. Desirably, the tracking device 56 is a radio frequency identification device (RFID). A radio frequency identification device (RFID) can be manufactured as a chip or as a microchip. By “chip” it is meant a minute slice of a semiconducting material, such as silicon or germanium, processed to have specified electrical characteristics. Some chips can contain an integrated circuit. By “microchip” it is meant a very small or abnormally small chip. Radio frequency identification devices (RFID's) are sometimes referred to as RFID glass tags. Radio frequency identification devices (RFID's) are commercially available from various vendors. One such vendor is DAP Inc. having an office in Baltimore, MD 21224, phone number (888) 327-8477. This company sells many kinds of microchips and RFID glass tags. One RFID glass tag is identified as model number: ISO 11784/85 PROTOCOL 4102 and this works well for this invention. The radio frequency identification device (RFID) can operate on different frequencies, for example, 125 kHz, 134.2 kHz, etc. Most radio frequency identification devices (RFID's) usually function from about −25° Celsius (C) to about 85° C. The memory storage of many radio frequency identification devices (RFID) is greater than about 10 years.

The tracking device 56 has a diameter d₄ and a length I₁. The diameter d₄ of the tracking device 56 is relatively small, usually less than about 0.2 of an inch. Desirably, the diameter d₄ of the tracking device 56 is less than about 0.15 of an inch. More desirably, the diameter d₄ of the tracking device 56 is less than about 0.1 of an inch. Even more desirable, the diameter d₄ of the tracking device 56 is less than about 0.09 of an inch. The length I₁ of the tracking device 56 is less than about 0.5 inches. Desirably, the length I₁ of the tracking device 56 is less than about 0.4 inches. More desirably, the length I₁ of the tracking device 56 is less than about 0.38 inches. Even more desirably, the length I₁ of the tracking device 56 is less than about 0.35 inches. The tracking device 56 weighs less than about 1 ounce. Desirably, the tracking device 56 weighs less than about 0.5 ounces. More desirably, the tracking device 56 weighs less than about 0.2 ounces. Even more desirably, the tracking device 56 weighs less than about 0.1 ounces.

The tracking device 56 can be free of a power source. In other words, the tracking device 56 does not need to contain a battery or any other kind of power unit. Alternatively, the tracking device 56 could contain a power source, if desired. Since the tracking device 56 typically will not contain a power source, it is relatively light in weight. The tracking device 56 does not emit an audible signal. Instead, the tracking device 56 contains a unique code. The code can be marked, printed, imprinted, embedded, be on an integrated circuit or otherwise be fixed to the tracking device 56. The code can be located on an external surface of the tracking device 56 or be located internally. The code can consist of one or more letters, numerals, dashes, lines, dots, icons, symbols, etc. Typically, the code is a combination of two or more numerals and letters. Desirably, the code is a combination of five or more numerals and letters arranged in a predetermined pattern. More desirably, the code is a combination of seven or more numerals and letters arranged in a predetermined pattern. The code can be a specific serial number which identifies the particular tracking device 56. The code on the tracking device 56 does not change and cannot be altered once it is affixed to the tracking device 56.

The tracking device 56 is designed such that one can use a scanner (not shown) to retrieve the code from the tracking device 56. When the tracking device 56 is a radio frequency identification device (RFID), the scanner can use a preselected radio frequency to detect and determine the code. Such a scanner is known to those skilled in the art and usually has an electronic display which shows the code in readable form. The scanner can also include an audible alarm or a flashing light which indicates when a tracking device 56 and/or its code have been detected. The scanner is designed to be slowly and steadily moved or waned, such as in a systematic pattern, over an article that contains the tracking device 56. The scanner is usually passed within inches of the tracking device 56. A distance of about a foot or less is sufficient for most scanners. Desirably, the scanner is brought within a range of from between about 1 inch to about 12 inches of the tracking device 56. More desirably, the scanner is brought within about 6 inches of the tracking device 56. The scanner can scan the tracking device 56 and retrieve the code instantaneously.

Referring now to FIGS. 5, 10 and 11, the third aperture 48 formed through the disk 38 is sized and configured to receive a first pre-assembled unit 58 of adhesive 60 and/or putty therein. By “adhesive” it is meant a substance, such as paste, glue, resin or cement that provides adhesion. By “putty” it is meant a dough-like cement made by mixing whiting and linseed oil, used to fill holes in woodworks and secure panes of glass. The adhesive 60 can be in liquid form or it can be very viscous. The adhesive 60 can also be an epoxy. By “epoxy” it is meant any of various usual thermosetting resins capable of forming tight cross-linked polymer structures characterized by toughness, strong adhesion, and low shrinkage, used especially in surface coatings and adhesives. The adhesive 60 can be a single compound. Alternatively, the adhesive 60 can be of the type that requires compound A to be mixed with compound B to produce a very strong, quick setting adhesive. When this is the case, the fourth aperture 50 is utilized to hold a second pre-assembled unit 62 of an adhesive 64. In this example, adhesive 60 is compound A and adhesive 64 is compound B.

It should be understood that the various items in the anti-theft deterrent protection kit 12 can be changed to accommodate the article to which the tracking device 56 is to be secured. For example, if the article is a construction tool, such as a compressor, a generator, a power skill saw, etc. the adhesive 60 can be replaced with a metal adhesive. A metal adhesive can look like an ordinary weld joint which makes it hard to detect. In addition, the tracking device 56 can be secured to a metal article by using a chemical adhesive, glue or by using solder. The anti-theft deterrent protection kit 12 can optionally contain: a wood plug, a metal plug, a composite plug, wood putty, a packet of sealant, a packet of varnish, a packet of shellac, a packet of stain, a packet of resinous material that matches the original finish on the article, etc. After an aperture has been drilled and the RFID tracking device 56 has been inserted therein, a plug or putty can fill the remainder of the aperture and a sealant, varnish, shellac or a stain can be applied to mask or cover the aperture so that no one will be able to readily notice that the article contains a tracking device 56.

It should also be understood that for some articles, it is not feasible to drill a hole or aperture into them. Doing so could break the article or diminish its value. In these cases, the tracking device can be secured to the article in some other fashion. For example, the tracking device 56 can be glued or bonded to the article, or be inserted into a crevice or nook of the article.

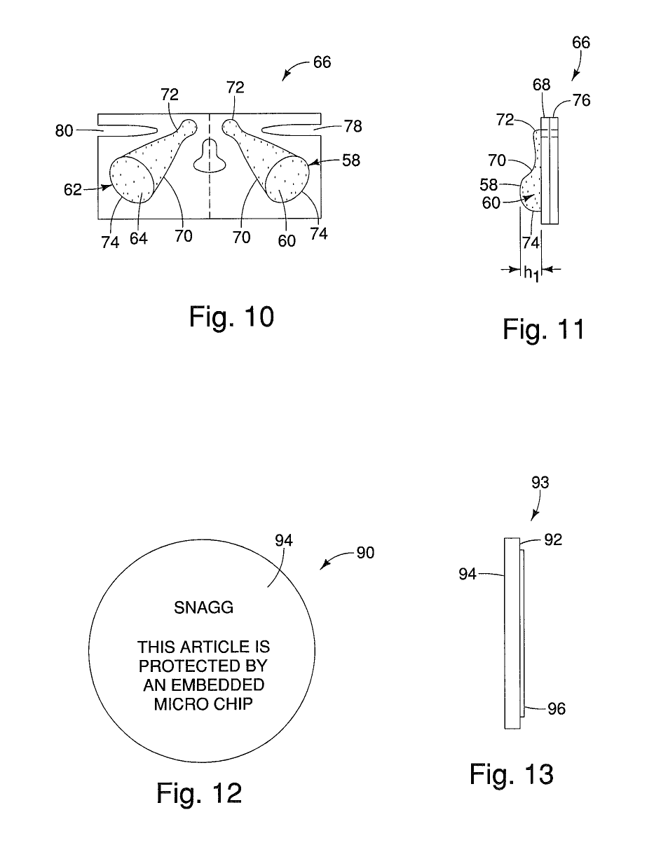

Referring to FIGS. 10 and 11, one embodiment of a packet 66 is depicted which is formed from a first layer 68 having a bubble 70 that protrudes outwardly therefrom. The bubble 70 can vary in configuration. In FIG. 10, the bubble 70 is depicted as having a tear drop profile when viewed from the front of the packet 66. The first layer 68 should be transparent or clear but doesn't have to be. The first layer 68 can be formed from a clear plastic material or from a clear film. The film can be thermoformed or be produced in some other fashion. The bubble 70 has a first end 72 and an oppositely aligned second end 74. The first end 72 is narrow and much smaller than the second end 74. For example, the second end 74 can be two or more times larger than the first end 72. Desirably, the second end 74 is at least three times larger than the first end 72. More desirably, the second end 74 is at least four times larger than the first end 72. The bubble 70 is filled with one of the adhesives 60 or 64. The bubble 70 has a height h₁ that can vary from the second end 74 to the first end 72. Usually, the bubble 70 has a greater height h₁ approximate the second end 74 and tapers, steps down or reduces in height h., as it approaches the first end 72. Alternatively, the bubble 70 could be constructed such that it has a constant height h₁.

Attached to the first layer 68 is a second layer 76. The second layer 76 can be conterminous with the first layer 68. The second layer 76 encloses the bubble 70. The bubble 70 can be filled with adhesive 60 or 64 before, during or after the second layer 76 is secured to the first layer 68. Desirably, the adhesive 60 or 64 is positioned in the bubble 70 before the second layer 76 is secured to the first layer 68. The second layer 76 can be formed from a variety of materials. The second layer 76 can be formed from paper, foil, plastic, film, a composite material, etc. Desirably, the second layer 76 is formed from foil, such as aluminum foil. The second layer 76 encloses the adhesive 60 or 64 in the bubble 70.

Still referring to FIGS. 10 and 11, the packet 66 also contains a notch 78 formed adjacent to the first end 72 of the first pre-assembled unit 58. The notch 78 can be formed through one or both the first and second layers, 68 and 76 respectively. In FIG. 11, the notch 78 is shown as being formed through both of the first and second layers, 68 and 76 respectively. The notch 78 is located in alignment with the first end 72 of the bubble 70 to facilitate tearing and opening the first pre-assembled unit 58. Once the first pre-assembled unit 58 is opened, the adhesive 60 can be dispensed in an orderly fashion. Likewise the packet 66 has a notch 80 formed adjacent to the first end 72 of the second pre-assembled unit 62. The notch 80 is formed through both of the first and second layers, 68 and 76 respectively. The notch 80 is located in alignment with the first end 72 of the bubble 70 to facilitate tearing and opening the second pre-assembled unit 62. Once the second pre-assembled unit 62 is opened, the adhesive 64 can be dispensed in an orderly fashion. If the two adhesives or resins 60 and 64 need to be mixed in order to react, they can be mixed at this time.

Referring again to FIG. 5, the package 10 further includes a first fastener 82 for temporarily securing or retaining the drill bit 52 in the first aperture 44. The first fastener 82 can be as simple as a piece of tape or be some other fastening mechanism known to those skilled in the art. The package 10 further includes a second fastener 84 for temporarily securing or retaining the tracking device 56 in the second aperture 46. Like the first fastener 82, the second fastener 84 can be as simple as a piece of tape or be some other fastening mechanism known to those skilled in the art.

The first and second pre-assembled units, 58 and 62 respectively, do not need to be fastened to temporarily secure or retain them in the third and/or fourth apertures, 48 and 50 respectively, because the packet 66 can be positioned between the back panel 18 and the disk 38. The size and configuration of the first and second pre-assembled units matches the size and configuration of the third and fourth apertures, 48 and 50 respectively. Therefore the apertures 48 and 50 will assist in holding the first and second pre-assembled units, 58 and 62 respectively, in place.

It should be understood that the drill bit 52 and the tracking device 56 could also be encased in a pre-assembled unit, envelope or packet, if desired, before they are positioned on the disk 38. If so, there may be no need for the first and second fasteners, 82 and 84 respectively.

Returning to FIG. 3, the package 10 further includes instructions. The instructions are depicted as being in the form of an instruction manual 86 containing a plurality of printed sentences. However, the instructions could be on an audible disk, be printed up in the form of diagrams or drawings, or be present in some other way known to those skilled in the art. The instruction manual 86 describes how one is to utilize the drill bit 52, the tracking device 56 and the adhesive 60 and/or 64. The instruction manual 86 can be temporarily retained in the front panel 16 of the case 14 by a plurality of projections 88. Four projections 88, 88, 88 and 88 are shown with two of the projections 88, 88 being located above the instruction manual 86, and two of the projections 88, 88 being located below the instruction manual 86. The four projections 88, 88, 88 and 88 can be formed when the front panel 16 is molded. The size shape, location and number of the projections 88, 88, 88 and 88 that are present can vary.

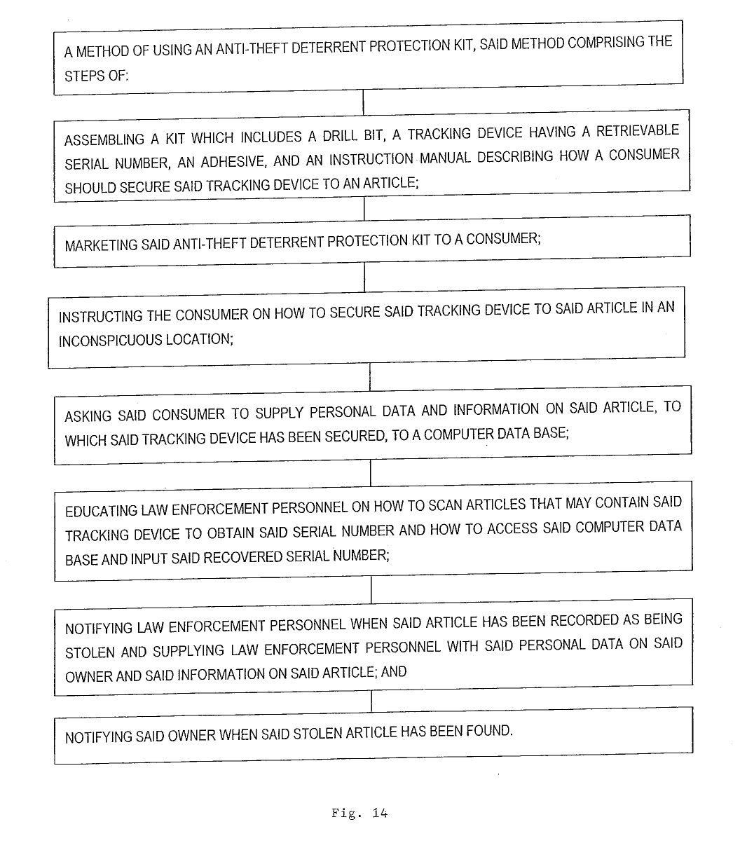

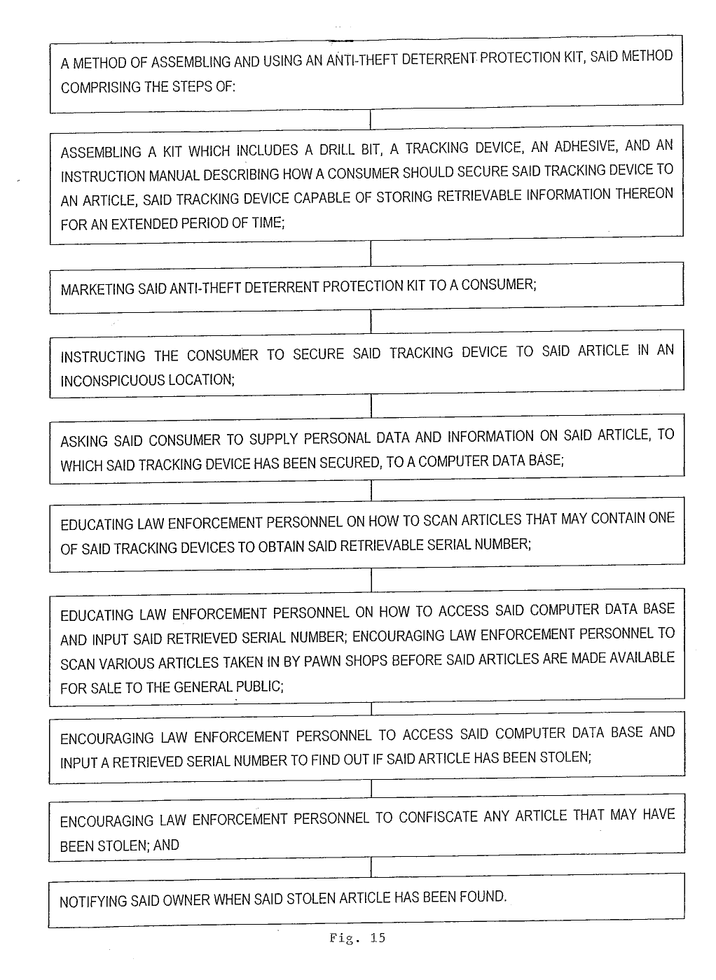

Referring now to FIGS. 12 and 13, an optional sticker 90 is shown. The sticker 90 has a first surface 92 and an opposing second surface 94. The first surface 92 contains an adhesive 96 for securing the sticker 90 onto an article, item or product. The second surface 94 contains a notice alerting potential thieves that the article to which the sticker 90 is attached is protected by a tractable device 56 such as a radio frequency identification microchip. The “notice” can be in written or printed form, or be a symbol or drawing. For example, the notice can consist of a printed warning, an icon with a diagonal line drawn therethrough, which convey to a person not to steal the article, or be a combination of both. The specific words or phrase printed on the sticker 90 can vary. One example, depicted in FIG. 12 is the statement: “THIS ARTICLE IS PROTECTED BY AN EMBEDDED MICROCHIP”.

The sticker 90 can optionally contain the name “SNAGG”, which is the name of the company that markets the anti-theft deterrent protection kits 12.

Referring now to FIG. 14, a flow diagram is shown which depicts a method of using the anti-theft deterrent protection kit 12. The method includes assembling a kit 12 which includes the drill bit 52, a tracking device 56, one or more adhesives 60 and/or 64, and an instruction manual 86. The instruction manual 86 describes in detail how a consumer is to secure the tracking device 56 to an article. Desirably, the tracking device 56 is a radio frequency identification microchip having a retrievable serial number. The method also includes marketing the anti-theft deterrent protection kit 12 to a consumer. The anti-theft deterrent protection kit 12 can be marketed through various channels. The antitheft deterrent protection kit 12 can be marketed using the Internet, using typical large retail stores, using medium size stores, using small stores, using specialty stores like a music store, a gun shop, etc., selling the kits 12 door to door, selling the kits 12 at sport shows, selling the kits 12 through magazine advertisements, etc. Some large retail stores include: WalMart, Target, Home Depot, Lowes, Gander Mountain, Dick's Sporting Goods, Fleet Farm, Farm & Fleet, Cabela's, etc.

The instruction manual 86 instructs the consumer to drill a hole or aperture in the article in an inconspicuous location. For example, if the article is a shotgun, the butt plate can be removed, by unscrewing the mounting screws, and drilling a hole in the stock. The tracking device 56 is inserted in the hole and the adhesive is used to hole it firmly in place. A wooden plug or putty can then be used to fill the remainder of the hole before the butt plate is again secured in place. For a musical instrument, such as a guitar, the tracking device 56 can be attached to an internal structural member. Sometimes it is not necessary to drill a hole and therefore the drill bit 52 is not needed. The article can be any known object, item or product made by man or found in nature. Such articles include but are not limited to: guns; musical instruments; bicycles; hand tools; construction tools like compressors, generators, hand held skill saw, power drills, circular saws, etc.; sporting goods; collectibles; computers; TV's; laptops; I-pads; I-phones; printers; monitors; etc. There are also a variety of specialized articles which are relatively small and can be easily carried off by one person. Musical instruments in particular are relatively expensive and can be easily stolen. Examples of such musical instruments include: stringed instruments, such as: guitars, violins, violas, cellos, lutes; wind instruments such as a horn, a French horn, a saxophone, a tuba, a trombone, a trumpet, etc.; high-pitched woodwind instruments such as a flute; and percussion instruments such as drums.

After the hole or aperture is drilled, the tracking device 56 is inserted into it. The adhesive 60 and/or 64 can be used to secure the tracking device 56 in the hole or aperture. If the adhesive consist of two resins 60 and 64 that need to be mixed together before being applied, the consumer will be instructed on how to efficiently do this. The adhesive 60 and/or 64 can be applied to the tracking device 56 before or after it is inserted into the hole or aperture. A plug or putty can then to used to fill the remainder of the hole, is desired. Likewise, a finish or stain can be applied over the plug or putty to camouflage the hole.

It should be understood that if the article is of such a nature that a hole or aperture cannot be drilled into it without destroying the article or detracting from its aesthetic appearance, then the consumer can simply glue or adhere the tracking device 56 to an inconspicuous location on the article. For example, if the article is a large sea shell, one would not necessarily want to drill a hole or aperture in it for it may decrease the value of the shell. Instead the tracking device 56 could be secured to an inside surface of the shell or to the back or bottom of the shell by an adhesive. The instruction manual 86 will explain this to the consumer.

After the tracking device 56 has been secured to a particular article, the consumer is instructed to supply pertinent personal data as well as information relating to the article to a computer data base. The computer data base is maintained by the company that sells the anti-theft deterrent protection kit 12. The computer data base is updated on a regular basis, such as daily. The personal data which the consumer is asked to supply can include one or more of the following: the name of the person who owns the article, his or her home address including street address, apartment number if applicable, city, state and zip code, home telephone number, cell phone number, e-mail address, fax number, etc. The information on the article can include one or more of the following: a description of the article; a model number; a serial number if available; the purchase date of the article; the retailer from whom the article was purchased, if applicable; the age of the article; the manufacturer of the article; and any distinguishing features of the article, etc. The consumer is able to update or change this information, free of charge, at any time since access to the database is available 24 hours per day every day of the year. For example, if the consumer moved to a new location, he or she could update the computer data base by connecting to the computer data base via the Internet or by phoning in or mailing in updates to the owner of the computer data base. The street address, phone number, e-mail address, fax number, etc. of the computer data base owner will be listed in the instruction manual. If the consumer legitimately sells the article to another person, he or she could supply this information to the computer database and/or instruct the new owner to supply his or her personal data to the computer data base. The new owner may or may not be charged a fee for entering his or her data since he or she did not originally purchase the anti-theft deterrent protection kit 12.

The method further includes educating law enforcement personnel on where to purchase a scanner and how to scan various articles using the scanner. Some law enforcement departments and agencies already own scanners that can readily detect radio frequency identification devices (RFID's). The needed scanners can be purchased from various vendors and operation of the scanners is fairly straight forward. By “law enforcement personnel” it is meant the personnel at local, county, state and federal departments and agencies, including but not limited to: local police, sheriffs, FBI agents, the Department of Justice agents, Alcohol, Tobacco and Firearms (ATF) agents, undercover officers, Homeland Security officers, agents of the Department of Natural Resources, game wardens, correctional officers, etc. The law enforcement personnel will be taught where the tracking devices 56 are usually located on various articles and what the serial numbers will look like. The law enforcement personnel are also educated on how to access the computer data base, free of charge, and input or retrieve any necessary information, such as serial numbers.

If the owner of the article is alerted to the fact that his or her article has been stolen, he or she can contact the data base and report this event along with the date the article was stolen. The legitimate owner should also notify the local police or other law enforcement personnel directly. In this way, the police will be in the loop. The police can also enter this information into the computer data base, free of charge. Either way, the fact that the article has been stolen will be imputed into the computer data base.

The computer data base will also notify law enforcement personnel when an article has been recorded as being stolen when the law enforcement personnel access the computer data base. The law enforcement personnel will be supplied with all of the pertinent personal data on the legitimate owner and the recorded information on the particular article. Should the law enforcement personnel find or recover the article, they can enter this fact into the computer data base. Upon receiving such a notice from the law enforcement personnel, the operator of the computer data base will notify the legitimate owner that his or her stolen article has been found and/or recovered and by whom and on what date.

Referring now to FIG. 15, another flow diagram is shown which depicts a variation to the method of assembling and using the anti-theft deterrent protection kit 12. The method includes assembling an anti-theft deterrent protection kit 12 which includes a drill bit 52, a tracking device 56, one or more adhesives 60 and/or 64, and an instruction manual 86. The instruction manual 86 teaches a consumer how to secure the tracking device 56 to an article. Desirably, the tracking device 56 is a radio frequency identification device (RFID). The tracking device 56 contains a code which can be retrieved using a scanner. The code is retrievable over an extended period of time, usually up to 10 years or more. The anti-theft deterrent protection kit 12 is then marketed to a consumer. The consumer is instructed to drill a hole or aperture in the article in an inconspicuous location and to use the adhesive to secure the tracking device in the hole or aperture. If it is not practical to drill a hole or aperture, the consumer can simple glue or adhere the tracking device 56 to the article. The consumer is then asked to supply or input pertinent personal data, as well as information on the article itself to a computer data base. The computer data base is maintained by the company that sells the anti-theft deterrent protection kits 12. Alternatively, the computer data base can be maintained by a company hired by the company that sells the anti-theft deterrent protection kits 12. The computer data base is operational and available to receive or disseminate information 24 hours per day, every day of the year.

Law enforcement personnel are educated on how to purchase and use scanners that can detect a radio frequency identification device (RFID). Law enforcement personnel are also educated as to where on an article the radio frequency identification devices (RFID's) are typically secured. Law enforcement personnel are further educated as to what the serial numbers look like, how many letters and numerals they contain and what serial numbers identify guns as opposed to some other articles. The company that sells the anti-theft deterrent protection kits 12 may sell certain kits 12 that are specifically tailored to attach the radio frequency identification device (RFID) only to firearms. In this case, a unique serial number or code on the radio frequency identification devices (RFID's) will immediately alert law enforcement personnel that the article is a firearm. The law enforcement personnel can retrieve the serial number or code imprinted or embedded in the radio frequency identification device (RFID) upon scanning the article. This retrievable serial number or code can be quickly checked against the records maintained in the computer data base. Law enforcement personnel are also educated on how to access the computer data base to input and/or to retrieve information on any desired serial number or code.

The law enforcement personnel are also encouraged to use a scanner to scan various articles taken in by pawn shops, gun stores, music shops or second hand stores before such articles are made available for sale to the general public. There are state and federal laws which require pawn shops and various retailers, who purchase or take in firearms as trade, to hold the firearms for thirty (30) days before they attempt to resell them. During this time, law enforcement personnel will visit the shops and scan each firearm. If the firearm has a tracking device 56 secured to it, the computer data base is checked to find out who the legitimate owner is and to determine if the firearm has been stolen. If the firearm has been listed as having been stolen or if someone other than the legitimate owner is trying to sell the firearm to the pawn shop or retailer, the police will immediately confiscate the gun. If the firearm has not been stolen but was subsequently sold by the original owner to another person and such information of the subsequent sale was never recorded in the computer data base, the police can require the second owner, who is trying to sell the firearm to the pawn shop, to input such information into the computer data base before he is allowed to resell the firearm.

By encouraging law enforcement personnel to access the computer data base and input a retrieved serial number or code to find out if the article has been stolen, there is less chance that stolen articles will be fenced through legitimate retailers. Hopefully, this will discourage thieves from stealing the article in the first place. Law enforcement personnel are further encouraged to confiscate any article that may have been stolen. Once the computer data base has received information from law enforcement personnel that an article has been found and recovered, the operator of the computer data base will notify the legitimate owner of this fact so that he or she may recover their property.

The information in the computer data base is accessible by law enforcement personnel, free of charge. The original purchaser of the anti-theft deterrent protection kit 12 can also access the computer data base, free of charge, to input or change information relating to the one tracking device 56 which was sold with the kit 12. The general public does not have access to the computer data base. Only certain scanners will be able to detect the radio frequency identification devices (RFID's) sold in the anti-theft deterrent protection kit 12. The general public will not have access to such scanners.

When a pawn shop or other retailer receives an article for resale, they will be required to have the seller fill out a written form identifying themselves and the article. When law enforcement personnel scan the article and access the computer data base, they can quickly identify the rightful owner. If the name of the rightful owner does not match the name of the person trying to sell the article, the article is immediately confiscated. The law enforcement personnel can go after and arrest the person who was trying to sell potentially stolen property. That person may be a criminal that is also wanted for other violations. In addition, the pawn shop or retailer will immediately see that the person trying to sell the article is not the rightful owner and they will be tipped off not to do business with that person again.

Using this method, an article can only be offered for resale after the original owner has signed off on the sale of the article or has notified the computer data base of a previous legitimate transfer. The computer data base will be updated to the new owner. When the pawn shop or retailer resells an article, it will have to notify the computer data base of this transfer to a new owner and supply all the pertinent information on the new owner. There will be a fee connected with doing this that can be passed on to the new owner. This information can only be transferred by formal papers prepared, signed or stamped by law enforcement personnel.

While the invention has been described in conjunction with a specific embodiment, it is to be understood that many alternatives, modifications and variations will be apparent to those skilled in the art in light of the foregoing description. Accordingly, this invention is intended to embrace all such alternatives, modifications and variations which fall within the spirit and scope of the appended claims.

1. An anti-theft deterrent protection kit comprising a case, a tracking device coupled with the case, and a securing means for securing the tracking device to an object.

2. An anti-theft deterrent protection kit as in claim 1, wherein the securing means includes an adhesive for securing the tracking device to an object.

3. An anti-theft deterrent protection kit as in claim 1, further comprising a drill bit for drilling a hole into an object.

4. An anti-theft deterrent protection kit as in claim 3, wherein the drill bit has a diameter suitable for drilling the hole in the object such as to house the tracking device.

5. An anti-theft deterrent protection kit as in claim 1, wherein the tracking device is a radio frequency identification device.

6. A method of using an anti-theft deterrent protection kit comprising the steps of:
assembling a kit which includes a drill bit, a tracking device, and an adhesive; and
utilizing the tracking device to attempt to recover an object.
